(19) United States
(12) Patent Application Publication
(10) Pub. No.: US 2006/0257563 A1
(43) Pub. Date: Nov. 16, 2006

(54) Method of fabricating silicon-doped metal oxide layer using atomic layer deposition technique

(76) Inventors: Seok-Joo Doh, Daegu (KR); Shi-Woo Rhee, Pohang-si (KR); Jong-Pyo Kim, Seongnam-si (KR); Jung-Hyoung Lee, Suwon-si (KR); Jong-Ho Lee, Suwon-si (KR); Yun-Seok Kim, Seoul (KR)

Correspondence Address: MILLS & ONELLO LLP, ELEVEN BEACON STREET, SUITE 605, BOSTON, MA, 02108, US

(21) Appl. No.: 11/329,696

(22) Filed: Jan. 11, 2006

Related U.S. Application Data
(63) Continuation-in-part of application No. 11/127,748, filed on May 12, 2005.
(60) Provisional application No. 60/618,106, filed on Oct. 13, 2004.

(30) Foreign Application Priority Data
Jan. 12, 2005 (KR) 10-2005-0002984

(51) Int. Cl. C23C 16/00

(52) U.S. Cl. 427/248.1

(57) ABSTRACT

There are provided methods of fabricating a silicon-doped metal oxide layer on a semiconductor substrate using an atomic layer deposition technique. The methods include an operation of repeatedly performing a metal oxide layer formation cycle K times and an operation of repeatedly performing a silicon-doped metal oxide layer formation cycle Q times. At least one of the values K and Q is an integer of 2 or more. K and Q are integers ranging from 1 to about 10 respectively. The metal oxide layer formation cycle includes the steps of supplying a metal source gas to a reactor containing the substrate, and then injecting an oxide gas into the reactor. The silicon-doped metal oxide layer formation cycle includes supplying a metal source gas including silicon into a reactor containing the substrate, and then injecting an oxide gas into the reactor. The sequence of operations of repeatedly performing the metal oxide layer formation cycle K times, followed by repeatedly performing the silicon-doped metal oxide layer formation cycle Q times, is performed one or more times until a silicon-doped metal oxide layer with a desired thickness is formed on the substrate. In addition, a method of fabricating a silicon-doped hafnium oxide (Si-doped HfO₂) layer according to a similar invention method is also provided.

### CROSS-REFERENCE TO RELATED APPLICATION

The present application is a continuation-in-part of U.S. patent application Ser. No. 11/127,748, filed May 12, 2005, which is based on U.S. Provisional Application No. 60/618,106, filed Oct. 13, 2004, the contents of which are incorporated in their entireties herein by reference. The present application claims the priority of Korean Patent Application No 2005-0002984, filed Jan. 12, 2005, the content of which is hereby incorporated herein by reference in its entirety.

### BACKGROUND OF INVENTION

1. Technical Field

The present invention relates to a method of fabricating a thin layer of a semiconductor device, and more particularly, to a method of fabricating a silicon-doped metal oxide layer on a semiconductor substrate using an atomic layer deposition (ALD) technique.

2. Discussion of the Related Art

With growing demand for highly-integrated semiconductor devices, a transistor and a capacitor as component semiconductor elements must be fabricated increasingly small to accommodate the smaller size requirements. The transistor and the capacitor elements typically include dielectrics. Efforts to reduce such dielectrics in both overall size and thickness have led, however, to many difficulties in fabrication.

For example, if a thickness of a gate dielectric layer as one component element of the transistor is formed too thin, there may result a deterioration in the insulation characteristics of the gate dielectric layer. A silicon oxide layer is normally used as a material to form the gate dielectric layer. In the case where a thickness of the silicon oxide layer is reduced to about 15 or less, it has been reported that there occurs a rapid increase in leakage current apparently caused by a direct tunneling effect in a gate electrode. As one solution to solve the problem described above, there have been efforts to study the use of high-k dielectrics which have a higher dielectric constant and a lower leakage current than those of the silicon oxide layer even when used in thin dielectric layers.

In recent years, a metal silicate layer, such as a hafnium silicate (HfSiOx) layer, and a silicon-doped metal oxide layer as the high-k dielectrics have been proposed. Each of the metal silicate layer and the silicon-doped metal oxide layer typically has an excellent mobility of carriers in comparison with other high-k dielectrics when such layers are employed in semiconductor transistors.

The conventional method of fabricating such a metal silicate layer uses physical vapor deposition (PVD) and chemical vapor deposition (CVD). As widely known, the PVD technique has serious limitations because of a poor step coverage and poor interface characteristics with a silicon substrate. The CVD technique also has serious limitations because of the need to use high temperatures to form thin films, and because of limitations in being able to precisely control the thickness of the thin film within a tolerance of several. Further, because a composition ratio in a PVD or CVD thin film is difficult to control, the conventional methods of fabricating the metal silicate layer were found not suitable to being employed to fabricate a highly-integrated semiconductor device.

Therefore, an atomic layer deposition (ALD) technique has been studied as an alternative method of fabricating a metal silicate layer and a silicon-doped metal oxide layer, each having a precise thickness by unit of an atomic layer to overcome the limitations of the CVD and PVD techniques. The ALD technique is a method of supplying source gases in a controlled, ordered sequence, with a discrete pulse type by time-division, rather than supplying source gases concurrently in order to form thin films. The supply of the various gases can be conducted by opening/closing valves provided to respective gas conduits with time variance such that process gases are not mixed, and each source gas can be individually supplied into a reactor according to a predetermined interval of time. When each of the source gases is supplied at a predetermined flow rate with such a time variance, a purge gas is also supplied between time intervals of supplying gases to remove the unreacted source gas remaining in the reactor. The ALD technique has the advantages of providing excellent step coverage and depositing a uniform thin film on a large-sized substrate, and also enabling precise control of the thickness of the thin film by controlling the number of repeated deposition cycles.

A general method of fabricating a metal silicate layer using the ALD technique has been disclosed in U.S. Patent Application Publication No. 2003-0031793 titled “METHOD FOR DEPOSITING A COATING HAVING A RELATIVELY HIGH DIELECTRIC CONSTANT ONTO A SUBSTRATE” by Cheng, et al., which publication is also incorporated herein by reference.

According to Cheng, et al., an aluminum oxide (Al₂O₃) layer, a tantalum oxide (Ta₂O₅) layer, and a hafnium oxide (HfO₂) layer as a metal oxide layer, and a zirconium silicate (SiZrO₄) layer and a hafnium silicate (HfSiOx) layer as a metal silicate layer, and the like, are formed on a semiconductor substrate. In specific, in Cheng et al. the semiconductor substrate is loaded into a reactor. A first precursor gas is supplied to the overall surface of a suitable substrate and then is purged from the reaction chamber. The first precursor, adsorbed on the overall surface of the substrate, is then oxidized by using an oxide gas such as oxygen, water vapor, dinitrogen monoxide (N₂O), or the like. These operations are repeatedly performed until a first thin film with a desired thickness is formed on the substrate. A second precursor gas is then supplied to the overall surface of the first thin film deposited on the substrate and then is purged. The second precursor, adsorbed on the overall surface of the first thin film on the substrate, is then oxidized by using an oxide gas such as oxygen, water vapor, dinitrogen monoxide (N₂O), or the like. These operations are repeatedly performed until a metal silicate layer with a desired thickness is formed on the first thin film layer.

Another method of fabricating a metal silicate layer has been disclosed in Japanese Patent Publication No. 2003-347298 titled “METHOD OF FABRICATING A SEMICONDUCTOR DEVICE AND AN APPARATUS OF PROCESSING A SUBSTRATE,” which publication is also incorporated herein by reference.

According to Japanese Patent Publication No. 2003-347298, a high-k dielectric including a hafnium silicate (HfSiOx) layer can be fabricated. In specific, a first layer source material gas is supplied to a suitable semiconductor substrate and then is purged from the reaction chamber. A remote-plasma oxidation (RPO) process is then performed to supply oxygen radicals to the first layer source material adsorbed on the substrate. These process steps are repeatedly performed for a determined number of repeated cycles in order to form a first layer of a desired thickness. A second material source gas is then supplied to the surface of the resultant structure, and then the layer surface is processed, i.e., the RPO process for supplying oxygen radicals to the surface is performed. These process steps are repeatedly performed for a determined number of repeated cycles so as to form a thin film of a desired thickness.

When the metal silicate layer is formed by one of the methods disclosed in U.S. Patent Application Publication No. 2003-0031793 or in Japanese Patent Publication No. 2003-347298, after the metal oxide layer formation process is repeatedly performed for a determined number of repeated cycles, a silicon source gas is supplied to the structure. Generally, however, such silicon source gas has a chemically stable structure relative to the metal oxide layer. As a result, there are many limitations in these methods of converting the metal oxide layer to the desired metal silicate layer using such silicon source gas. For example, it has been found to be very difficult to convert the metal oxide layer to the metal silicate layer after repeatedly performing the metal oxide layer formation process by about 10 times or more, and thereafter supplying the silicon source gas. Instead of such processing leading to the formation of the desired unitary or integrated metal silicate layer, the silicon oxide layer may be separately stacked on the metal oxide layer, or the reaction and/or formation of the silicon oxide layer on the metal oxide layer may not occur at all or only along portions of the surface and, even then, not uniformly.

### SUMMARY OF THE INVENTION

Therefore, the present invention provides a method of fabricating a silicon-doped metal oxide layer on a suitable semiconductor substrate, wherein the method is capable of precisely and relatively uniformly controlling the thicknesses of the thin films and also of controlling the composition ratios of metal and silicon in the resultant silicon-doped metal oxide layer.

Another more specific object of the present invention is to provide a method of fabricating a silicon-doped hafnium oxide layer on a semiconductor substrate while also precisely controlling thicknesses of the thin films and also controlling the composition ratios of hafnium and silicon in the resultant silicon-doped hafnium oxide layer.

In accordance with an exemplary embodiment, the present invention provides a method of fabricating a silicon-doped metal oxide layer using an atomic layer deposition technique. The method generally includes the sequential steps of loading a substrate into a reactor or chamber and then supplying a suitable metal source gas into the reactor or chamber having the substrate in order to form a chemical adsorption layer including the metal on the substrate surface. Typically following a purging step, an oxide gas is supplied into the reactor to react with the chemical adsorption layer including the metal, thereby forming a metal oxide layer on the substrate. The sequential operations of supplying a metal source gas to the reactor, purging, and supplying an oxide gas to form a metal oxide layer (the metal/oxide steps) are repeatedly performed a determined number, e.g., K, times. A suitable metal source gas including silicon is then supplied into the reactor in order to form a metal chemical adsorption layer including silicon on the metal oxide layer previously formed on the substrate. Typically following another purging step, an oxide gas is supplied into the reactor to react with the metal oxide layer and the metal chemical adsorption layer including silicon deposited thereon, thereby forming a silicon-doped metal oxide layer. The sequential operations of supplying a metal source gas including silicon to the reactor, purging and supplying an oxide gas to form a silicon-doped metal oxide layer are repeatedly performed a determined number, e.g., Q, times. Here, at least one of the values K and Q is preferably an integer of 2 or more. The complete sequential operation beginning with the step of supplying a metal source gas through the step of forming a silicon-doped metal oxide layer is performed at least one time, and may be performed two or more times, thereby forming a silicon-doped metal oxide layer having a desired thickness.

In accordance with exemplary embodiments of this invention, the method may further advantageously include such related steps as cleaning (or purging) the reactor after a step of supplying the various reactant gases. In specific, the unreacted metal source gas remaining in the reactor after the step of forming the chemical adsorption layer including the metal may be exhausted to clean the inside of the reactor. The unreacted oxide gas and any gaseous reaction byproducts remaining in the reactor after the step of forming the metal oxide layer may be exhausted to clean the inside of the reactor. The unreacted metal source gas including silicon remaining in the reactor after the step of forming the metal chemical adsorption layer including silicon may likewise be exhausted to clean the inside of the reactor. The unreacted oxide gas and any gaseous reaction byproducts remaining in the reactor after forming the silicon-doped metal oxide layer may be exhausted to clean the inside of the reactor. In one invention embodiment, a purge gas may be supplied into the reactor in order to exhaust the unreacted gases and the byproducts. The purge gas normally will comprise a substantially inert gas (relative to the reaction environment) such as argon (Ar), helium (He), or nitrogen (N₂).

In accordance with other exemplary embodiments, the metal source gas including silicon may be a material having the general chemical formula MCl₂[N(Si(CH₃)₃)₂]₂, wherein M is a member selected from the group consisting of Hf, Zr, Ta, Al and Ti. In particular, the metal source gas including silicon may be a material having the chemical formula HfCl₂[N(Si(CH₃)₃)₂]₂.

In accordance with other exemplary embodiments, the number of cycle repetitions K and Q, as defined above, are preferably in the range of 1 to about 10. For example, the number K may for some common applications advantageously be in the range of 1 to 5, and the number Q may be 1. If the number K is 10 or more, however, it has been found that the metal oxide layer formed during the operation of forming the metal oxide layer has a chemically stable structure. Because such a metal oxide layer (where K≧10) has a chemically stable structure, it makes it more difficult to form a successful and generally uniform silicon-doped metal oxide layer. Further, it has been found that if the number Q is 10 or more, even though the metal source gas including silicon may be further supplied to the silicon-doped metal oxide layer, the further formation of a metal chemical adsorption layer including silicon typically does not occur. That is, if the number Q is 10 or more, the silicon-doped metal oxide layer is not further formed. The silicon-doped metal oxide layer according to this invention may be represented by the general chemical formula, MₓSi₁₋ₓO₂ wherein: M is an element selected from the group consisting of Hf, Zr, Ta, Al and Ti, and “x” represents a composition ratio of the metal M relative to silicon in the silicon-doped metal oxide layer. By determining and controlling the numbers K and Q during the layer formation operation, the “x” may be controlled, for example in the range of about 0.85˜0.95. That is, by appropriately controlling the number of film deposition cycles (K and Q respectively), a silicon-doped metal oxide layer with a desired composition ratio can be formed on the semiconductor substrate.

In accordance with a more specific exemplary embodiment, the present invention provides a method of fabricating a silicon-doped hafnium oxide layer on a suitable semiconductor substrate using an atomic layer deposition technique. The method generally includes the sequential steps of loading a substrate into a reactor or chamber and then supplying a tetrakis (ethylmethylamino) hafnium (TEMAH) (Hf [N(CH₃)C₂H₅]₄) gas into the reactor having the substrate in order to form a chemical adsorption layer including hafnium (Hf) on the substrate surface. Typically following a purging step, an oxide gas is supplied into the reactor to react with the chemical adsorption layer including hafnium (Hf), thereby forming a hafnium (Hf) oxide layer on the substrate. The sequential operations of supplying the TEMAH gas to the reactor, purging, and supplying an oxide gas to form the hafnium (Hf) oxide layer are repeatedly performed a determined number, e.g., K, times. A HfCl₂[N(Si(CH₃)₃)₂]₂ gas is then supplied into the reactor in order to form a hafnium (Hf) chemical adsorption layer including silicon on the hafnium oxide layer previously formed on the substrate. Typically following another purging step, an oxide gas is supplied into the reactor to react with the hafnium (Hf) oxide layer and the hafnium (Hf) chemical adsorption layer including silicon deposited thereon, thereby forming a silicon-doped hafnium oxide (Si-doped HfO₂) layer. The operations of supplying the HfCl₂[N(Si(CH₃)₃)₂]₂ gas to the reactor, purging, and supplying an oxide gas to form the silicon-doped hafnium oxide layer are repeatedly performed a determined number, e.g., Q, times. The complete sequential operation beginning with the step of supplying the TEMAH gas through the step of forming the silicon-doped hafnium oxide layer is performed at least one time, and may be performed two or more times, thereby forming a silicon-doped hafnium oxide layer having a desired thickness.

In accordance with exemplary embodiments of this invention, the method may further advantageously include such related steps as cleaning (or purging) the reactor after a step of supplying the various reactant gases. In specific, the unreacted TEMAH gas remaining in the reactor after the step of forming the chemical adsorption layer including hafnium (Hf) can be exhausted to clean the inside of the reactor. The unreacted oxide gas and any gaseous reaction byproducts remaining in the reactor after the step of forming the hafnium (Hf) oxide layer can be exhausted to clean the inside of the reactor. The unreacted HfCl₂[N(Si(CH₃)₃)₂]₂ gas remaining in the reactor after the step of forming the hafnium (Hf) chemical adsorption layer including silicon can likewise be exhausted to clean the inside of the reactor. The unreacted oxide gas and any gaseous reaction byproducts remaining in the reactor after forming the silicon-doped hafnium oxide layer can be exhausted to clean the inside of the reactor. Examples of suitable purge gases for use in such reactor cleaning steps are as previously described.

In accordance with other exemplary embodiments, the number of cycle repetitions, K and Q, as defined above, are preferably in the range of 1 to about 10. The silicon-doped hafnium oxide layer according to this invention may be represented by the general chemical formula, HfₓSi₁₋ₓO₂ wherein “x” represents a composition ratio of hafnium (Hf) relative to hafnium+silicon in the silicon-doped hafnium oxide layer. By determining and controlling the numbers K and Q during the layer formation operation, the “x” may be controlled, for example in the range of about 0.85˜0.95. That is, by appropriately controlling the number of film deposition cycles (K and Q respectively), a silicon-doped hafnium oxide (HfₓSi₁₋ₓO₂) layer with a desired composition ratio can be formed on the substrate.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a process flow chart generally illustrating a method of fabricating a silicon-doped metal oxide layer using an ALD technique according to the present invention;

FIG. 2 is a diagram of a single complete layer deposition cycle (which may include a number K of metal/oxide steps and a number Q of metal-silicon/oxide steps) illustrating a method of fabricating a silicon-doped metal oxide layer using an ALD technique according to the present invention;

FIG. 3 is a graph illustrating the thicknesses of different silicon-doped hafnium oxide layers formed on semiconductor substrates, in two examples according to preferred embodiments of the present invention, in one example not in accordance with preferred embodiments of this invention, plotted against spaced measured positions along the respective semiconductor substrates;

FIG. 4 is a graph illustrating different characteristics of leakage current for different silicon-doped hafnium oxide layers formed according to experiment examples of the present invention; and

FIG. 5 is a graph illustrating different characteristics of positive bias temperature instability (PBTI) for different silicon-doped hafnium oxide layers formed according to experiment examples of the present invention.

### DETAILED DESCRIPTION OF THE INVENTION

The present invention will now be described more fully hereinafter with reference to the accompanying drawings, in which preferred embodiments of the invention are shown. It will be understood, however, that this invention may be embodied in many different forms and should not be construed as being limited to the embodiments set forth herein. Rather, these embodiments are provided so that this disclosure will be thorough and complete, and will fully convey the scope of the invention to those skilled in the art. Like numbers in the drawings are used to refer to like elements throughout the specification.

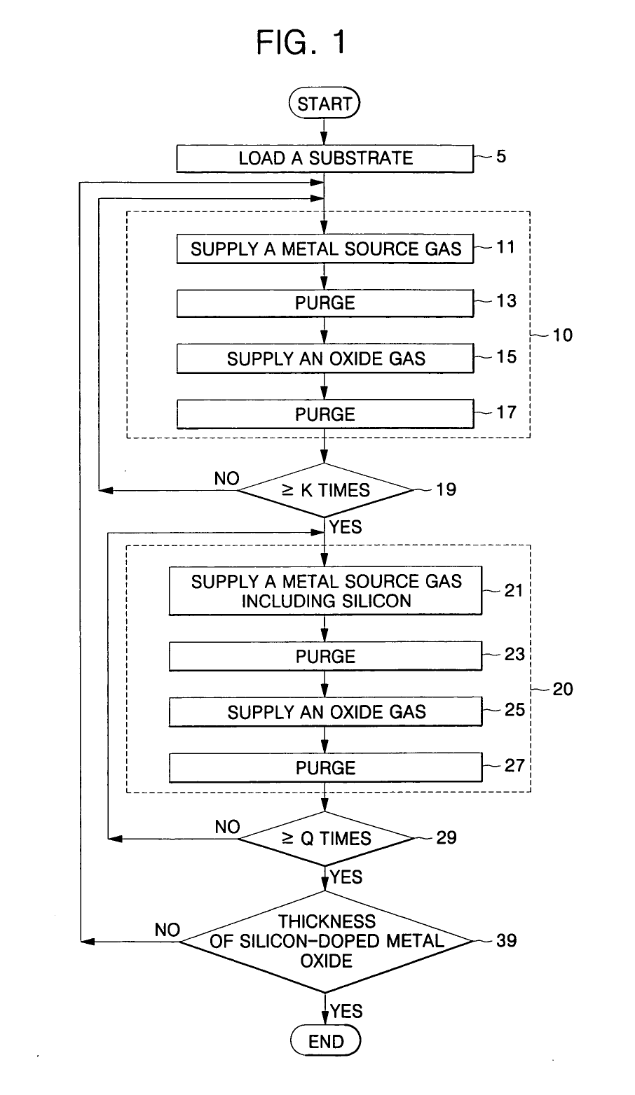

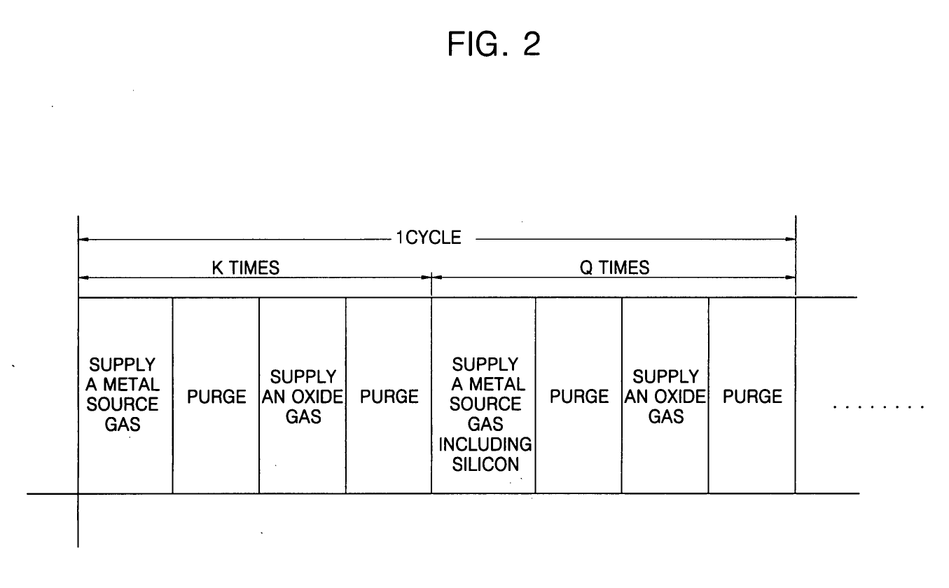

FIG. 1 is a process flow chart generally illustrating a method of fabricating a silicon-doped metal oxide layer using an ALD technique according to the present invention, and FIG. 2 is a diagram of a single complete layer deposition cycle illustrating a method of fabricating a silicon-doped metal oxide layer using an ALD technique according to the present invention.

Referring to FIGS. 1 and 2, the general methods of fabricating a silicon-doped metal oxide layer according to embodiments of the present invention include an initial or preliminary step of loading a suitable semiconductor substrate into a reactor or chamber comprising part of an atomic layer deposition (ALD) system (step 5 of FIG. 1).

The reactor may be a slice type or batch type. The substrate may be a semiconductor substrate such as a silicon substrate, and the substrate may have an isolation layer already formed thereon. Further, the substrate may have a three-dimensional structure, such as a lower electrode of a cylindrical-shaped capacitor formed thereon, and thus may include a plurality of different surfaces located in different planes. The methods of this invention may be used to form a silicon-doped metal oxide layer on any or all of such substrate surfaces.

The inside of the reactor is heated to a temperature suitable to performing the fabrication processes of this invention. For example, an appropriate temperature for the processes of this invention is in the range of about 250° C. to 600° C.

The metal oxide layer formation cycle 10 (comprising the separate, sequential individual steps 11, 13, 15 and 17) is repeatedly performed K times on the substrate, thereby forming a metal oxide layer with a desired thickness. The metal oxide layer formation cycle 10 may include the individual steps of supplying a metal source gas as defined herein (step 11 of FIG. 1), exhausting unreacted metal source gas remaining in the reactor to clean the inside of the reactor (step 13 of FIG. 1), supplying an oxide gas into the reactor (step 15 of FIG. 1), and cleaning the inside of the reactor (step 17 of FIG. 1).

In specific, the metal source gas is supplied into the reactor having the substrate loaded therein (step 11 of FIG. 1). In one embodiment, the metal source gas is a material having the general chemical formula MX₄, wherein M is an element selected from the group consisting of Hf, Zr, Ta, Al and Ti, and X is an element selected from the group consisting of F, Cl, Br and I. In another embodiment, the metal source gas is a material having the general chemical formula M(NRR′)₄, wherein M is an element selected from the group consisting of Hf, Zr, Ta, Al and Ti; N is nitrogen; R is a chemical group selected from the group consisting of H, Me, Et and ⁱPr; and R′ is a chemical group selected from the group consisting of H, Me, Et and ⁱPr. Further, the metal source gas may also specifically be tetrakis (ethylmethylamino) hafnium (TEMAH) (Hf[N(CH₃)C₂H₅]₄). For example, in the case of supplying TEMAH as the metal source gas, the pulse time for supplying the metal source gas may be about 0.2˜2 seconds. As a result, a chemical adsorption layer including the metal is formed along exposed surface(s) of the substrate. After the chemical adsorption layer including the metal is formed, the metal source gas remaining in the reactor is exhausted to clean the inside of the reactor (step 13 of FIG. 1). In order to exhaust the metal source gas, or to assist in such step, a purge gas may be supplied to the inside of the reactor. The purge gas normally comprises a substantially inert gas such as argon (Ar), helium (He), or nitrogen (N₂). Then, the oxide gas is supplied into the reactor (step 15 of FIG. 1). The oxide gas may be at least one member selected from the group consisting of oxygen (O₂), ozone (O₃), water (H₂O) and hydrogen peroxide (H₂O₂). As a result, the chemical adsorption layer including the metal and the oxide gas react with each other so as to form a metal oxide layer on the substrate. Then, the oxide gas remaining inside the reactor and gaseous byproducts produced by the reaction of the chemical adsorption layer including the metal and the oxide gas are exhausted to clean the inside of the reactor (step 17 of FIG. 1). In order to exhaust the oxide gas and the reaction byproducts, or to assist in such step, a purge gas may be supplied to the inside of the reactor. The purge gas normally comprises a substantially inert gas such as argon (Ar), helium (He), or nitrogen (N₂). A check is then performed, manually or automatically, to determine whether or not a metal oxide layer with a desired thickness has been formed on the substrate. The metal oxide layer formation cycle 10 is repeatedly performed K times until the metal oxide layer having a desired thickness is formed on the substrate (step 19 of FIG. 1). Here, the number K is an integer in the range of 1 to about 10. That is, the number of repetitions K of the metal oxide layer formation cycle 10 is preferably in the range of one time to ten times.

Next, a silicon-doped metal oxide layer formation cycle 20 (comprising the separate, sequential individual steps 21, 23, 25 and 27) is repeatedly performed Q times on the substrate having the metal oxide layer formed thereon. The silicon-doped metal oxide layer formation cycle 20 may include the individual steps of supplying a metal source gas including silicon as defined herein (step 21 of FIG. 1), exhausting unreacted metal source gas including the silicon remaining in the reactor to clean the inside of the reactor (step 23 of FIG. 1), supplying an oxide gas into the reactor (step 25 of FIG. 1), and cleaning the inside of the reactor (step 27 of FIG. 1).

In specific, the metal source gas including silicon is supplied into the reactor having the substrate loaded therein (step 21 of FIG. 1). The metal source gas including silicon may be a material having the general chemical formula MCl₂[N(Si(CH₃)₃)₂]₂, wherein M is a member selected from the group consisting of Hf, Zr, Ta, Al and Ti. Specifically, the metal source gas including silicon may be a material having the chemical formula HfCl₂[N(Si(CH₃)₃)₂]₂. As a result of the step of supplying the metal source gas including silicon (step 21), a metal chemical adsorption layer including the silicon is formed on the surface of the substrate having the metal oxide layer previously formed thereon. After the metal chemical adsorption layer including silicon is formed, the metal source gas including silicon remaining in the reactor is exhausted to clean the inside of the reactor (step 23 of FIG. 1). In order to exhaust the metal source gas including silicon, or to assist in such step, a purge gas may be supplied to the inside of the reactor. The purge gas normally comprises a substantially inert gas such as argon (Ar), helium (He), or nitrogen (N₂). Then, the oxide gas is supplied into the reactor (step 25 of FIG. 1). The oxide gas may be at least one member selected from the group consisting of oxygen (O₂), ozone (O₃), water (H₂O) and hydrogen peroxide (H₂O₂). For example, in the case that the metal source gas including silicon is HfCl₂[N(Si(CH₃)₃)₂]₂, a preferred oxide gas may be H₂O. As a result, the metal chemical adsorption layer including silicon and the oxide gas react with each other so as to form the silicon-doped metal oxide layer on the substrate. Reaction byproducts may be produced in the reactor by the reaction of the metal chemical adsorption layer including silicon and the oxide gas Then, the oxide gas remaining inside the reactor and the byproducts are exhausted to clean the inside of the reactor (step 27 of FIG. 1): In order to exhaust the oxide gas and the reaction byproducts, or to assist in such step, a purge gas may be supplied to the inside of the reactor. The purge gas normally comprises a substantially inert gas such as argon (Ar), helium (He), or nitrogen (N₂). A check is then performed, manually or automatically, to determine whether or not a silicon-doped metal oxide layer having a desired composition ratio has been formed on the substrate. The silicon-doped metal oxide layer formation cycle 20 is repeatedly performed Q times until the silicon-doped metal oxide layer having a desired composition ratio is formed on the substrate (step 29 of FIG. 1). Here, the number Q is an integer in the range of 1 to about 10. That is, the number of repetitions Q of the silicon-doped metal oxide layer formation cycle 20 is preferably in the range of one time to ten times.

In the method of fabricating a silicon-doped metal oxide layer according to preferred embodiments of the present invention, the numbers K and Q must be determined so as not to exceed 10 times respectively. For example, the number K may be in the range of 1 to 5, and the number Q may be 1. If the number K is 10 or more, the metal oxide layer formed by the metal oxide layer formation cycle 10 results in a very chemically stable structure. Formation of a metal oxide layer having such a chemically stable structure, however, makes it very difficult for the silicon-doped metal oxide layer to be formed during the silicon-doped metal oxide layer formation cycle 20. That is, the metal chemical adsorption layer having the silicon formation reaction may not occur due to the previously formed metal oxide layer having such a chemically stable structure. Further, if the number Q is 10 or more, additional metal chemical adsorption layer including silicon typically will not be formed even though the metal source gas including silicon is further supplied to the previously formed silicon-doped metal oxide layer. That is, even if the silicon-doped metal oxide layer formation cycle 20 is performed beyond 10 times, additional silicon-doped metal oxide layer generally is not further deposited thereon. The silicon-doped metal oxide layer formed in accordance with this invention may be represented by the general chemical formula MₓSi₁₋ₓO₂ wherein: M may be an element selected from the group consisting of Hf, Zr, Ta, Al and Ti, and “x” represents a composition ratio of the metal relative to metal+silicon. The “x” can be controlled to be in a range of about 0.85˜0.95 by appropriately controlling the number of repeated cycles, K and Q respectively. That is, a silicon-doped metal oxide layer having a desired composition ratio “x” can be formed on the substrate by controlling the number K of the metal oxide layer formation cycles and the number Q of the silicon-doped metal oxide layer formation cycles.

As a result, the silicon-doped metal oxide layer formation cycle includes an operation of performing the metal oxide layer formation cycle 10 K times and an operation of performing the silicon-doped metal oxide layer formation cycle 20 Q times. Then, a thickness of the silicon-doped metal oxide layer is checked (step 39 of FIG. 1). The silicon-doped metal oxide layer formation cycle is performed at least one time, or is repeated until the silicon-doped metal oxide layer with a desired thickness is formed on the substrate. That is, until the silicon-doped metal oxide layer with a desired thickness is formed on the substrate, the sequence of operations of repeatedly performing the metal oxide layer formation cycle 10 K times, followed by repeatedly performing the silicon-doped metal oxide layer formation cycle 20 Q times, is performed one or more times.

More specifically, a silicon-doped hafnium oxide (Si-doped HfO₂) layer can be formed according to embodiments of the present invention. Hereinafter, a method of fabricating the silicon-doped hafnium oxide (Si-doped HfO₂) layer according to embodiments of the present invention will be explained in reference to FIGS. 1 and 2.

The method of fabricating the silicon-doped hafnium oxide (Si-doped HfO₂) layer includes an initial or preliminary step of loading a suitable semiconductor substrate into a reactor section of ALD equipment (step 5 of FIG. 1).

The inside of the reactor is heated to a temperature suitable for performing the fabrication processes of this invention. For example, the appropriate temperature for the processes may be in the range of about 250° C. to 600° C.

A hafnium oxide layer formation cycle 10 is repeatedly performed on the substrate K times, thereby forming a hafnium (Hf) oxide layer with a desired thickness. The hafnium oxide layer formation cycle 10 may include the individual steps of supplying a hafnium (Hf) source gas (step 11 of FIG. 1), exhausting unreacted hafnium (Hf) source gas remaining in the reactor to clean the inside of the reactor (step 13 of FIG. 1), supplying an oxide gas into the reactor (step 15 of FIG. 1), and cleaning the inside of the reactor (step 17 of FIG. 1).

In specific, the hafnium (Hf) source gas is supplied into the reactor having the substrate loaded therein (step 11 of FIG. 1). In one embodiment, the hafnium (Hf) source gas is a material having the general chemical formula HfX₄, wherein X may be an element selected from the group consisting of F, Cl, Br and I. In another embodiment, the hafnium (Hf) source gas is a material having the general chemical formula Hf(NRR′)₄, wherein R is a chemical group selected from the group consisting of H, Me, Et and ⁱPr, and R′ is also a chemical group selected from the group consisting of H, Me, Et and ⁱPr. Further, the hafnium (Hf) source gas may also specifically be tetrakis (ethylmethylamino) hafnium (TEMAH) (Hf[N(CH₃)C₂H₅]₄). For example, in the case of supplying TEMAH as the metal source gas, the pulse time for supplying the TEMAH gas may be about 0.2˜2 seconds. As a result, a chemical adsorption layer including hafnium (Hf) is formed along exposed surface(s) of the substrate. After the chemical adsorption layer including hafnium (Hf) is formed, the hafnium (Hf) source gas remaining in the reactor is exhausted to clean the inside of the reactor (step 13 of FIG. 1). In order to exhaust the hafnium (Hf) source gas, a purge gas may be supplied to the inside of the reactor. The purge gas normally comprises a substantially inert gas such as argon (Ar), helium (He), or nitrogen (N₂). Then, the oxide gas is supplied into the reactor (step 15 of FIG. 1). The oxide gas may be at least one member selected from the group consisting of oxygen (O₂), ozone (O₃), water (H₂O) and hydrogen peroxide (H₂O₂). In the case that the TEMAH is used for the hafnium (Hf) source gas, the oxide gas may advantageously be ozone (O₃). The ozone easily oxidizes typical impurities that may be stuck on the hafnium. That is, the ozone treatment is effective to remove impurities on the hafnium. As a result, the chemical adsorption layer including hafnium and the oxide gas react with each other so as to form a hafnium (Hf) oxide layer on the substrate. Then, the oxide gas remaining inside the reactor and gaseous byproducts produced by the reaction of the chemical adsorption layer and the oxide gas are exhausted to clean the inside of the reactor (step 17 of FIG. 1). In order to exhaust the oxide gas and the reaction byproducts, a purge gas may be supplied to the inside of the reactor. The purge gas normally comprises a substantially inert gas such as argon (Ar), helium (He), or nitrogen (N₂). It is then checked whether the hafnium (Hf) oxide layer with a desired thickness has been formed or not. The hafnium (Hf) oxide layer formation cycle 10 is repeatedly performed K times until the hafnium (Hf) oxide layer having a desired thickness is formed on the substrate (step 19 of FIG. 1). Here, the number K is an integer in the range of 1 to about 10. That is, the number of repetitions K of the hafnium oxide layer formation cycle 10 is preferably in the range of one time to ten times.

Next a silicon-doped hafnium oxide layer formation cycle 20 is performed Q times on the substrate having the hafnium (Hf) oxide layer formed thereon, thereby forming a silicon-doped hafnium oxide layer. The silicon-doped hafnium oxide layer formation cycle 20 may include the individual steps of supplying HfCl₂[N(Si(CH₃)₃)₂]₂ gas (step 21 of FIG. 1), exhausting unreacted HfCl₂[N(Si(CH₃)₃)₂]₂ gas remaining in the reactor to clean the inside of the reactor (step 23 of FIG. 1), supplying an oxide gas into the reactor (step 25 of FIG. 1), and cleaning the inside of the reactor (step 27 of FIG. 1).

In specific, the silicon-doped hafnium oxide layer can be formed according to the embodiments of the present invention in the same general manner as the method explained in reference to FIGS. 1 and 2. For example, if the metal source gas including silicon applied is HfCl₂[N(Si(CH₃)₃)₂]₂ gas, the oxide gas may advantageously be H₂O. As a result, the hafnium (Hf) chemical adsorption layer including silicon and the oxide gas react with each other so as to form the silicon-doped hafnium oxide layer on the substrate. A check is then performed to determine whether the silicon-doped hafnium oxide layer having a desired composition ratio has been formed or not. The silicon-doped hafnium oxide layer formation cycle 20 is repeatedly performed Q times until the silicon-doped hafnium oxide layer having a desired composition ratio is formed on the substrate (step 29 of FIG. 1). Here, the number Q is an integer in the range of 1 to about 10. That is, the number of repetitions Q of the silicon-doped hafnium oxide layer formation cycle 20 is preferably in the range of one time to ten times.

In the method of fabricating the silicon-doped hafnium oxide layer according to preferred embodiments of the present invention, the numbers K and Q must be determined or chosen so as not to exceed 10 times respectively. For example, the number K may be in the range of 1 to 5, and the number Q may be 1. More preferably, the number K may be 3, and the number Q may be 1. If the number K is 10 or more, the hafnium oxide layer formed by the hafnium oxide layer formation cycle 10 results in a very chemically stable structure. Formation of a hafnium oxide layer having such a chemically stable structure, however, makes it very difficult for the silicon-doped hafnium oxide layer to be formed during the silicon-doped metal oxide layer formation cycle 20. That is, the silicon-doped metal oxide layer formation reaction may not occur due to the previously formed hafnium oxide layer having such a chemically stable structure. Further, if the number Q is 10 or more, additional hafnium chemical adsorption layer including silicon typically will not be formed on the silicon-doped hafnium oxide layer, even though the HfCl₂[N(Si(CH₃)₃)₂]₂ gas is further supplied to the previously formed silicon-doped hafnium oxide layer. That is, even if the silicon-doped metal oxide layer formation cycle 20 is performed beyond 10 times, additional silicon-doped hafnium oxide layer generally is not further deposited thereon. The silicon-doped hafnium oxide layer formed in accordance with this invention may be represented by the general chemical formula HfₓSi₁₋ₓO₂ wherein “x” represents a composition ratio of hafnium (Hf) relative to hafnium+silicon. The “x” can be controlled to be in a range of about 0.85˜0.95, for example, by appropriately controlling the number of repeated cycles, K and Q respectively. That is, a silicon-doped hafnium oxide (Si-doped HfO₂) layer having a desired composition ratio “x” can be formed on the substrate by controlling the number K of the hafnium oxide layer formation cycles and the number Q of the silicon-doped metal oxide layer formation cycles.

As described in connection with the silicon-doped metal oxide layer formation cycle, the silicon-doped hafnium oxide (Si-doped HfO₂) layer formation cycle includes an operation of performing the hafnium oxide layer formation cycle 10 K times and an operation of performing the silicon-doped hafnium oxide layer formation cycle 20 Q times. Then, a thickness of the silicon-doped hafnium oxide (Si-doped HfO₂) layer is checked (step 39 of FIG. 1). The silicon-doped hafnium oxide layer formation cycle is performed at least one time, or is repeated until the silicon-doped hafnium oxide (Si-doped HfO₂) layer with a desired thickness is formed on the substrate. That is, until the silicon-doped hafnium oxide (Si-doped HfO₂) layer with a desired thickness is formed on the substrate, the sequence of operations of repeatedly performing the hafnium oxide layer formation cycle 10 K times, followed by repeatedly performing the silicon-doped hafnium oxide layer formation cycle 20 Q times, is performed one or more times.

<Experiment Examples>

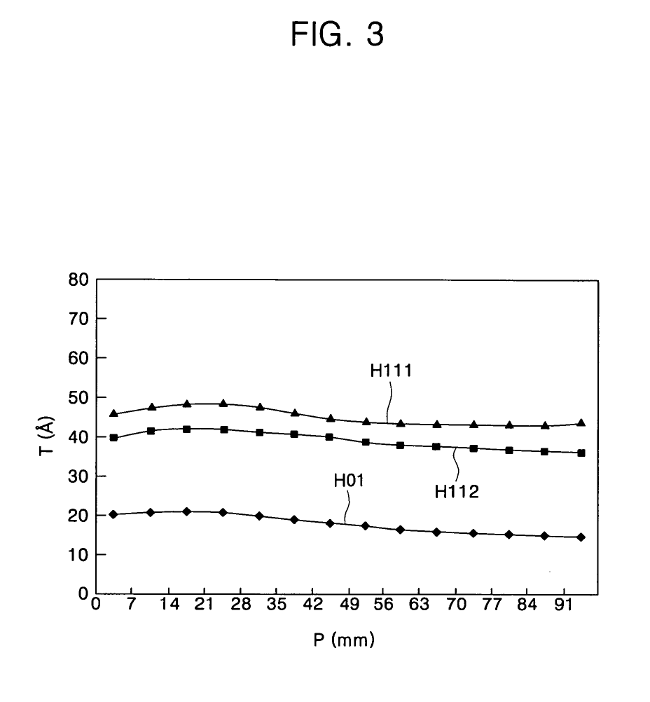

FIG. 3 is a graph illustrating thicknesses of different silicon-doped hafnium oxide layers formed on semiconductor substrates according to a conventional method and two embodiments of the present invention. A horizontal axis P in the graph of FIG. 3 represents measured positions along a semiconductor substrate, and the measured positions are spaced at intervals of 7 mm outwards from the center of the semiconductor substrate. A vertical axis T in the graph of FIG. 3 represents measured thickness of a silicon-doped hafnium oxide layer formed on the substrate, and the unit of thickness is. In the three experiment examples shown in FIG. 3, the same temperature of the reactor and deposition pressure among the various process conditions were used for forming the respective silicon-doped hafnium oxide layers, for comparison purposes. In specific, the temperature of the reactor was set at 320° C., and the deposition pressure was set at 0.2 torr.

Referring to FIG. 3, a curve H01 illustrates a thickness of a silicon-doped hafnium oxide layer formed on a semiconductor substrate according to the conventional method. The curve H01 shows the result of the experiment in which K was set to be 0, Q was set to be 1, and the silicon-doped hafnium oxide layer formation cycle was repeatedly performed 250 times as described previously in reference to FIGS. 1 and 2 to make this conventional example comparable to the two examples according to the present invention. Here, the number K representing the number of times of performing the hafnium oxide layer formation cycle 10 was 0. That is, the hafnium oxide layer formation cycle 10 was omitted. Further, the hafnium source gas including the silicon used in the silicon-doped hafnium oxide layer formation cycle 20 was HfCl₂[N(Si(CH₃)₃)₂]₂, and the oxide gas was H₂O. Further, the pulse time of supplying the HfCl₂[N(Si(CH₃)₃)₂]₂ gas was 1 second. As a result, a silicon-doped hafnium oxide layer was formed having a somewhat varying thickness of about 18 (more or less) as shown by the curve H01 in FIG. 3. In general, it is known that the thickness of the natural oxide layer formed on the semiconductor substrate is typically about 10 to 20. Thus, according to the result shown by the curve H01, it can be concluded that a desired thickness of the silicon-doped hafnium oxide layer was not deposited on the substrate when the HfCl₂[N(Si(CH₃)₃)₂]₂ gas treatment (steps 21-27 in FIG. 1) was practiced without also practicing the metal source gas treatment (steps 11-17 in FIG. 1).

Curves H111 and H112 illustrate thicknesses of different silicon-doped hafnium oxide layers formed on semiconductor substrates according to embodiments of the present invention.

The curve H111 in FIG. 3 shows the result of the experiment in which K and Q were set to be 1 respectively, and the silicon-doped hafnium oxide layer formation cycle was performed 250 times as described in reference to FIGS. 1 and 2. Here, the number K bf performing the hafnium oxide layer formation cycle 10 was 1. Further, the hafnium source gas used was TEMAH, and the oxide gas was ozone. Also, the number Q of performing the silicon-doped hafnium oxide layer formation cycle 20 was 1. The hafnium source gas including silicon used in the silicon-doped hafnium oxide layer formation cycle 20 was HfCl₂[N(Si(CH₃)₃)₂]₂, and the oxide gas was H₂O. Further, the pulse time of supplying the HfCl₂[N(Si(CH₃)₃)₂]₂ gas was 1 second. As a result, a silicon-doped hafnium oxide layer was formed having a thickness of about 48 as shown by the curve H111 in FIG. 3. The curve H112 in FIG. 3 shows the result of the experiment in which K and Q were set to be 1 respectively, and the silicon-doped hafnium oxide layer formation cycle was performed 250 times as described in reference to FIGS. 1 and 2. Here, the hafnium source gas used was TEMAH, and the oxide gas was ozone. The hafnium source gas including the silicon used in the silicon-doped hafnium oxide layer formation cycle 20 was HfCl₂[N(Si(CH₃)₃)₂]₂, and the oxide gas was H₂O. Further, the pulse time of supplying the HfCl₂[N(Si(CH₃)₃)₂]₂ gas was 0.2 seconds. As a result, a silicon-doped hafnium oxide layer was formed having a thickness of about 40 as shown by the curve H112 in FIG. 3.

According to the results of the experiment examples shown in FIG. 3, a silicon-doped hafnium oxide layer with a predetermined thickness can best be formed by appropriately controlling the number of repetition cycles, that is, the numbers K and Q, from 1 to about 10 or less.

Table 1 shows the results of an X-Ray photoelectron spectroscopy (XPS) analysis of three different silicon-doped hafnium oxide layers (Si-doped HfO₂) formed on substrates in accordance with this invention.

TABLE 1

| K:Q | Si (%) | Hf/(Si + Hf) |
|---|---|---|
| 3:1 | 1.8 | 0.94 |
| 1:1 | 3.8 | 0.88 |
| 1:3 | 4.0 | 0.86 |

Referring to Table 1, when depositing the silicon-doped hafnium oxide layer by setting K to be 3 and Q to be 1 as described previously in reference to FIGS. 1 and 2, the silicon content was determined to be 1.8%, and the composition ratio of hafnium (Hf) relative to hafnium+silicon was 0.94. Here, the hafnium source gas used was TEMAH, and the hafnium source gas including silicon applied was HfCl₂[N(Si(CH₃)₃)₂]₂. When depositing the silicon-doped hafnium oxide layer by setting K and Q to be 1 respectively, the silicon content was determined to be 3.8%, and the composition ratio of hafnium (Hf) relative to hafnium+silicon was 0.88. Further, when depositing the silicon-doped hafnium oxide layer by setting K to be 1 and Q to be 3, the silicon content was determined to be 4.0%, and the composition ratio of hafnium (Hf) relative to hafnium+silicon was 0.86.

According to the results of Table 1, it can be concluded that a silicon-doped hafnium oxide layer having a desired composition ratio can be obtained by appropriately controlling the number of repetition cycles, that is, the numbers K and Q, from 1 to about 10 or less.

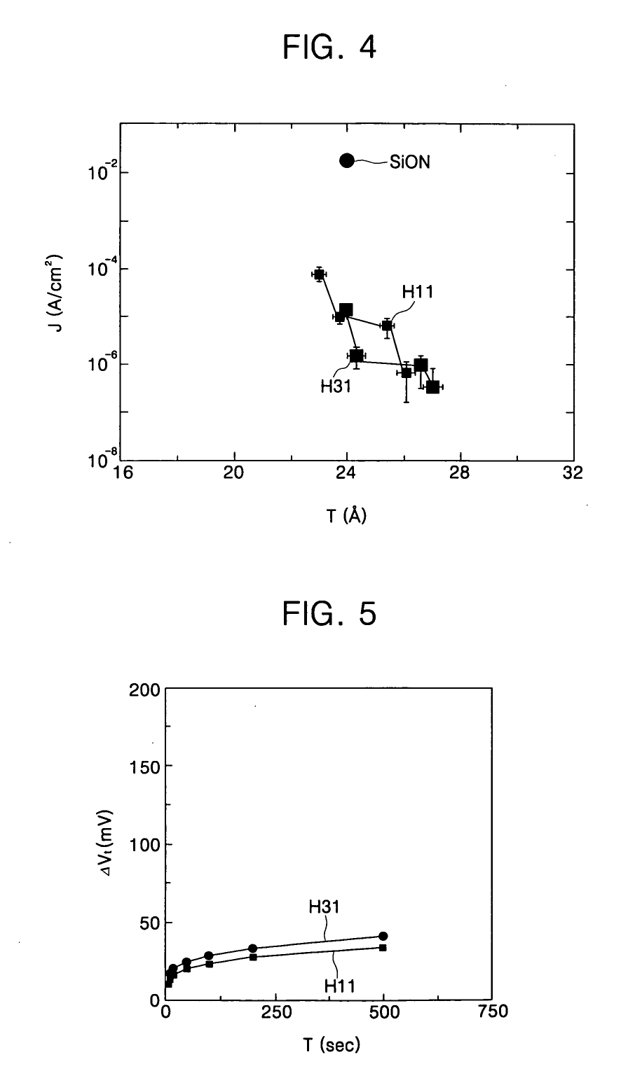

FIG. 4 is a graph illustrating different characteristics of leakage current for different silicon-doped hafnium oxide layers formed according to the present invention when such layers are applied as gate dielectric layers of MOS transistors. A horizontal axis T in the graph of FIG. 4 represents accumulative capacitance equivalent thicknesses of the gate dielectric layers, scaled in units of angstrom ( ). A vertical axis J in the graph of FIG. 4 represents leakage current measured when applying 1.5V gate bias, scaled in units of A/cm².

Dot SiON in FIG. 4 shows a leakage current characteristic obtained from the result of a comparative experiment in which a siliconoxynitride layer is adopted as a gate dielectric layer. Curve H11 in FIG. 4 shows a leakage current characteristic obtained from the result of the experiment in which the silicon-doped hafnium oxide layer formed by setting K and Q to be 1 respectively, as described in reference to FIGS. 1 and 2, is adopted as a gate dielectric layer. Further, curve H31 in FIG. 4 shows a leakage current characteristic obtained from the result of the experiment in which the silicon-doped hafnium oxide layer formed by setting K to be 3 and Q to be 1 is applied as a gate dielectric layer.

As shown in relation to the dot SiON, the curve H11 and the curve H31 in FIG. 4 demonstrate that the silicon-doped hafnium oxide layers formed in accordance with the present invention have improved (i.e., lower) leakage current characteristics relative to the siliconoxynitride layers formed in accordance with conventional techniques.

FIG. 5 is a graph illustrating different characteristics of positive bias temperature instability (PBTI) for different silicon-doped hafnium oxide layers according to experiment examples of the present invention. A horizontal axis T in the graph of FIG. 5 represents a stress time applied to a gate dielectric layer of nMOS transistor, scaled in time units of seconds (sec.). A vertical axis (Δl_{d}) in the graph of FIG. 5 represents variations of threshold voltage before and after applying stress, scaled in units of mV.

The nMOS transistors used in the experiments of the present invention were fabricated using a pattern with a width W of 10 um and a length L of 1 um. Further, the gate dielectric layers of the several nMOS transistors were formed of different silicon-doped hafnium oxide layers, each with a thickness of 30. As described in reference to FIGS. 1 and 2, each complete silicon-doped hafnium oxide layer formation cycle included an operation of performing the hafnium oxide layer formation cycle 10 K times and an operation of performing the silicon-doped hafnium oxide layer formation cycle 20 Q times. Further, the hafnium source gas used in the hafnium oxide layer formation cycle 10 was TEMAH, and the oxide gas was ozone. Further, the hafnium source gas including silicon used in the silicon-doped hafnium oxide layer formation cycle 20 was HfCl₂[N(Si(CH₃)₃)₂]₂. The K and the Q values were set differently. Further, a temperature of positive bias temperature instability (PBTI) conditions was 125° C. Further, a bias applied to the nMOS transistors was 7.5 MV/cm.

Curve H31 in FIG. 5 shows PBTI characteristics relative to a silicon-doped hafnium oxide layer formed under the conditions of K=3, Q=1. Further, a curve H11 in FIG. 5 shows PBTI characteristic relative to a silicon-doped hafnium oxide layer formed under the conditions of K=1, Q=1. Based on these results, it can be concluded that the demonstrated PBTI characteristics were excellent when the variation of threshold voltage before and after applying stress was 50 mV or less. As shown in FIG. 5, all of the experiment examples of the present invention showed excellent PBTI characteristics.

According to the present invention as described above, a complete silicon-doped metal oxide layer formation cycle includes an operation of performing the metal oxide layer formation cycle K times and an operation of performing the silicon-doped metal oxide layer formation cycle Q times. The K and the Q numbers are integers that may range from 1 to about 10. Composition ratios of metal relative to silicon in the silicon-doped metal oxide layer can be controlled by appropriately controlling the number of repeated cycles, K and Q respectively, in each silicon-doped metal oxide layer formation cycle. Further, the thickness of a silicon-doped metal oxide layer can be precisely controlled by appropriately controlling the number of repeated silicon-doped metal oxide layer formation cycles. Therefore, a silicon-doped metal oxide layer having a desired composition ratio and a uniform desired thickness can be fabricated using an ALD technique according to the present invention.

What is claimed is:

1. A method of fabricating a silicon-doped metal oxide layer on a substrate using an atomic layer deposition technique, said method comprising the sequential steps of:
(a) loading a substrate into a reactor;
(b) supplying a metal source gas containing a desired metal into the reactor having the substrate under reaction conditions to form a chemical adsorption layer including the desired metal on the substrate;
(c) supplying an oxide gas into the reactor under reaction conditions to react with the chemical adsorption layer including the desired metal to form a metal oxide layer including the desired metal on the substrate;
(d) repeatedly performing steps (b) and (c) sequentially K times;
(e) supplying a metal source gas including silicon into the reactor under reaction conditions to form a metal chemical adsorption layer including silicon on the metal oxide layer on the substrate;
(f) supplying an oxide gas into the reactor under reaction conditions to react with the metal oxide layer and the metal chemical adsorption layer including silicon to form a silicon-doped metal oxide layer;
(g) repeatedly performing steps (e) and (f) sequentially Q times, wherein at least one of the values K and Q is an integer of 2 or more; and
(h) performing the operations of steps (b), (c), (d), (e), (f) and (g) sequentially at least one time, thereby forming a silicon-doped metal oxide layer with a desired thickness.

2. The method according to claim 1, further comprising the steps of:
exhausting unreacted metal source gas remaining in the reactor after each step (b) to clean the inside of the reactor before step (c);
exhausting unreacted oxide gas and reaction byproducts remaining in the reactor after each step (c) to clean the inside of the reactor before step (d);
exhausting unreacted metal source gas including silicon remaining in the reactor after each step (e) to clean the inside of the reactor before step (f); and
exhausting unreacted oxide gas and reaction byproducts remaining in the reactor after each step (f) to clean the inside of the reactor before step (g).

3. The method according to claim 1, wherein the value of K and the value of Q ranges from 1 to 10.

4. The method according to claim 1, wherein said reaction conditions include a temperature of the reactor in the range of about 250° C. to 600° C.

5. The method according to claim 1, wherein the metal source gas is a material having the general chemical formula MX₄, wherein M is a member selected from the group consisting of Hf, Zr, Ta, Al and Ti, and X is a member selected from the group consisting of F, Cl, Br and I.

6. The method according to claim 1, wherein the metal source gas is a material having the general chemical formula M(NRR′)₄, wherein M is a member selected from the group consisting of Hf, Zr, Ta, Al and Ti; R is a member selected from the group consisting of H, Me, Et and ⁱPr; and R′ is a member selected from the group consisting of H, Me, Et and ⁱPr.

7. The method according to claim 1, wherein the metal source gas is tetrakis (ethylmethylamino) hafnium (TEMAH) having the general chemical formula Hf[N(CH₃)C₂H₅]₄.

8. The method according to claim 1, wherein the oxide gas is at least one member selected from the group consisting of H₂O, O₃, O₂ and H₂O₂.

9. The method according to claim 1, wherein the metal source gas including silicon is a material having the general chemical formula MCl₂[N(Si(CH₃)₃)₂]₂, wherein M is a member selected from the group consisting of Hf, Zr, Ta, Al and Ti.

10. The method according to claim 1, wherein the metal source gas including silicon is a material having the chemical formula HfCl₂[N(Si(CH₃)₃)₂]₂.

11. The method according to claim 1, wherein a composition ratio of a metal element relative to the metal plus silicon in the silicon-doped metal oxide layer is in the range of about 0.85˜0.95.

12. A method of fabricating a silicon-doped hafnium oxide layer on a substrate using an atomic layer deposition technique, said method comprising the sequential steps of:
(a) loading a substrate into a reactor;
(b) supplying a tetrakis (ethylmethylamino) hafnium (TEMAH) (Hf[N(CH₃)C₂H₅]₄) gas into the reactor having the substrate under reaction conditions to form a chemical adsorption layer including hafnium (Hf) on the substrate;
(c) supplying an oxide gas into the reactor under reaction conditions to react with the chemical adsorption layer including hafnium (Hf), to form a hafnium (Hf) oxide layer on the substrate;
(d) repeatedly performing steps (b) and (c) sequentially K times;
(e) supplying HfCl₂[N(Si(CH₃)₃)₂]₂ gas into the reactor under reaction conditions to form a hafnium (Hf) chemical adsorption layer including silicon on the hafnium (Hf) oxide layer on the substrate;
(f) supplying an oxide gas into the reactor under reaction conditions to react with the hafnium (Hf) oxide layer and the hafnium (Hf) chemical adsorption layer including silicon to form a silicon-doped hafnium oxide (Si-doped HfO₂) layer;
(g) repeatedly performing steps (e) and (f) sequentially Q times; and
(h) performing the operations of steps (b), (c), (d), (e), (f) and (g) sequentially at least one time, thereby forming a silicon-doped hafnium oxide layer with a desired thickness.

13. The method according to claim 12, further comprising the steps of:
exhausting unreacted TEMAH gas remaining in the reactor after each step (b) to clean the inside of the reactor before step (c);
exhausting unreacted oxide gas and reaction byproducts remaining in the reactor after each step (c) to clean the inside of the reactor before step (d);
exhausting unreacted HfCl₂[N(Si(CH₃)₃)₂]₂ gas remaining in the reactor after each step (e) to clean the inside of the reactor before step (f); and
exhausting unreacted oxide gas and reaction byproducts remaining in the reactor after each step (f) to clean the inside of the reactor before step (g).

14. The method according to claim 12, wherein the value of K and the value of Q ranges from 1 to 10.

15. The method according to claim 12, wherein said reaction conditions include a temperature of the reactor in the range of about 250° C. to 600° C.

16. The method according to claim 12, wherein the oxide gas is at least one member selected from the group consisting of H₂O, O₃, O₂ and H₂O₂.

17. The method according to claim 12, wherein a composition ratio of hafnium (Hf) element relative to hafnium plus silicon in the silicon-doped hafnium oxide layer is in the range of about 0.85˜0.95.
